(19) United States
(12) Patent Application Publication
(10) Pub. No.: US 2025/0054831 A1
(43) Pub. Date: Feb. 13, 2025

(54) METHOD FOR FABRICATING TOPSIDE COOLED SEMICONDUCTOR PACKAGES BY FILM ASSISTED MOLDING AND A SEMICONDUCTOR PACKAGE

(71) Applicant: Infineon Technologies AG, Neubiberg (DE)

(72) Inventors: Chee Yang Ng, Muar (MY); Kok Yau Chua, Melaka (MY); Nurfarena Othman, Melaka (MY); Milad Mostofizadeh, München (DE); Joseph Victor Soosai Prakasam, Chennai (IN)

(21) Appl. No.: 18/785,745

(22) Filed: Jul. 26, 2024

(30) Foreign Application Priority Data
Aug. 10, 2023 (DE) 102023121373.3

(51) Int. Cl. H01L 23/367; H01L 21/56; H01L 21/683; H01L 23/00; H01L 23/498; H01L 23/544

(52) U.S. Cl. CPC H01L 23/3672; H01L 21/565; H01L 21/6836; H01L 23/49838; H01L 23/544; H01L 24/40; H01L 24/96; H01L 24/97; H01L 24/16; H01L 2223/54493; H01L 2224/16225; H01L 2224/40245; H01L 2224/96; H01L 2224/97; H01L 2924/13055; H01L 2924/1815

(57) ABSTRACT

A method for fabricating one or more semiconductor packages includes: a substrate layer including one or more electrical contact regions; connecting a semiconductor die with one of the electrical contact regions; providing a heat dissipation member including one or more contact areas; attaching a tape to a backside of the heat dissipation member so that opposing ends of the tape extend beyond opposing side edges of the heat dissipation member; connecting a frontside of the heat dissipation member with the semiconductor die by coupling at least one contact area with the semiconductor die; placing a mold tool above the heat dissipation member and the substrate layer with the opposing ends of the tape extending out of the mold tool so that the tape is removable from outside the mold tool; filling an encapsulant into the mold cavity; and removing the tape.

### TECHNICAL FIELD

The present disclosure is related to a method for fabricating one or more semiconductor packages and to a semiconductor package.

### BACKGROUND

Discrete semiconductor power packages are continuously developed further in the direction of higher efficiency and output power. Decisive factors here are increasing the switching speed and the current density of the packages to be developed. In new applications like “green energy” e.g. solar modules, ESS (energy storage systems), electric vehicle charging, the product lifetime is also limited by power cycling robustness, therefore high current in combination with high power cycling is offering new business potentials.

In particular wide bandgap devices such as GaN and SiC transistor dies can achieve far higher current densities compared to standard Si devices. Therefore, either smaller dies can be used with the same current output, or a higher current output can be achieved with the same size of the die. However, if the current density is increased, it must be ensured that the excess heat generated by the power consumption is dissipated from the package as quickly as possible, since the temperatures in such power transistors may well reach 150° C. and higher during operation. Concepts such as topside cooling in particular play an important role in this context.

For these and other reasons there is a need for the present disclosure.

### SUMMARY

A first aspect of the present disclosure is related to a method for fabricating one or more semiconductor packages, the method comprising providing a substrate layer comprising one or more electrical contact regions, connecting a semiconductor die with one of the electrical contact regions, providing a heat dissipation member comprising one or more contact areas, attaching a tape to a backside of the heat dissipation member so that opposing ends of the tape extend beyond opposing side edges of the heat dissipation member, connecting a frontside of the heat dissipation member with the semiconductor die by coupling at least one contact area with the die, forming a mold cavity by placing a mold tool above the heat dissipation member and the substrate layer with the opposing ends of the tape extending out of the mold tool so that the tape is removable from outside the mold tool, filling an encapsulant into the mold cavity, and removing the tape.

According to an embodiment of the method of the first aspect, the tape is pulled out of the mold tool after curing of the encapsulant.

According to an embodiment of the method of the first aspect, a first part of the tape is disposed between the mold tool and the heat dissipation member and a second part of the tape is disposed between the mold tool and the substrate layer so that a space between the mold tool and the substrate layer forms the mold cavity.

According to an embodiment of the method of the first aspect, the method further comprises after pulling out the tape, singulating the assembly into the two or more semiconductor packages.

According to an embodiment of the method of the first aspect, the method further comprises providing the substrate layer with a regular arrangement of a plurality of electrical contact regions. According to a further example thereof, the heat dissipation member is provided with a regular arrangement of a plurality of contact areas. According to another example, the regular arrangement of the plurality of contact areas comprises a matrix-like arrangement. According to another example, the plurality of contact areas comprises a plurality of pairs of contact areas.

According to an embodiment of the method of the first aspect, the substrate layer is one or more of a laminate layer, a printed circuit board (PCB), a leadframe, a direct copper bond (DCB), an active metal brazed (AMB), or an insulated metal substrate (IMS).

According to an embodiment of the method of the first aspect, the heat dissipation member comprises one or more of a leadframe, a direct copper bond (DCB), an active metal brazed (AMB), a passivated aluminum plate, an insulated metal substrate, a conductive clip or a ceramic material.

According to an embodiment of the method of the first aspect, the method further comprises providing the tape so that after placing the mold tool above the heat dissipation member and the substrate layer, the tape extends to the outside of the mold tool by a length in a range from 2 mm to 4 mm.

According to an embodiment of the method of the first aspect, the semiconductor die comprises ones or more of a semiconductor transistor die, a power transistor die, a GaN transistor die, or a SiC transistor die.

A second aspect of the present disclosure is related to a method for fabricating a plurality of semiconductor packages, the method comprising providing a heat dissipation member comprising one or more contact areas and one or more contact elements, applying one or more semiconductor dies onto the one or more contact areas, connecting an electrical connector between the semiconductor die and one of the contact elements, attaching a tape to a backside of the electrical connector so that opposing ends of the tape extend beyond opposing side edges of the heat dissipation member, placing an upper mold tool above the electrical connector and one of the contact elements and a lower mold tool to a backside of the heat dissipation member so that a first part of the tape is disposed between the upper mold tool and the electrical connector and a second part of the tape is disposed between the upper mold tool and the contact element so that a space between the upper mold tool and the lower mold tool forms a mold cavity, filling the mold cavity with an encapsulant, and removing the tape.

According to an embodiment of the method of the second aspect, the method further comprises placing two or more semiconductor dies onto two or more contact areas, connecting two or more electrical connectors between the two or more semiconductor dies and one of the contact elements, placing an upper mold tool above the electrical connector and the two outermost contact elements, and after pulling out the tape, singulating the assembly into the two or more semiconductor packages.

According to an embodiment of the method of the second aspect, the electrical connector comprises a clip.

According to an embodiment of the method of the second aspect, wherein the semiconductor die comprises ones or more of a semiconductor transistor die, a power transistor die, a GaN transistor die, or a SiC transistor die.

A third aspect of the present disclosure is related to a semiconductor package comprising a substrate layer, a contact area, at least one tie bar connected to a side face of the contact area, a semiconductor die disposed on the contact area so that it is connected to the substrate layer in a flip-chip configuration, an encapsulant covering an upper face of the substrate layer and partly embedding the semiconductor die, the contact area and the tie bar, wherein a main face of the contact area remote from the semiconductor die and a side face of the tie bar are exposed to the outside.

According to an embodiment of the semiconductor package of the third aspect, the semiconductor package further comprises two tie bars connected to opposing side faces of the contact area and comprising side faces exposed to the outside.

According to an embodiment of the semiconductor package of the third aspect, the semiconductor package further comprises tape adhesive marks in the form of notches in the encapsulant at side edges of the contact area.

A forth aspect of the present disclosure is related to a semiconductor package comprising a substrate layer comprising a die pad and a contact element, a semiconductor die connected to the die pad in a flip-chip configuration, an electrical connector connected between an upper face of the semiconductor die and the contact element, an encapsulant covering an upper face of the substrate layer and partly embedding the semiconductor die, wherein a main face of the electrical connector remote from the semiconductor die is exposed to the outside.

According to an embodiment of the semiconductor package of the forth aspect, the electrical connector comprises a clip.

According to an embodiment of the semiconductor package of the forth aspect, the semiconductor package further comprises tape adhesive marks in the form of notches in the encapsulant at side edges of the electrical connector.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description.

The elements of the drawings are not necessarily to scale relative to each other. Like reference numerals designate corresponding similar parts.

FIGS. 1A to 1G illustrate cross-sectional side views of an example of a method for fabricating semiconductor packages.

FIGS. 2A to 2D illustrate top views on a matrix-like arrangement of a plurality of contact areas of an example of a method for fabricating semiconductor packages.

FIGS. 3A to 3C illustrate a top view on a matrix-like arrangement of a plurality of pairs of contact areas of an example of a method for fabricating semiconductor packages.

FIGS. 4A to 4H illustrate cross-sectional side views of an example of a method for fabricating a semiconductor package comprising a clip.

FIGS. 5A and 5B illustrate a cross-sectional side view (FIG. 5A) and a top view (FIG. 5B) of an example of a semiconductor package.

FIGS. 6A and 6B illustrate a cross-sectional side view (FIG. 6A) and a top view (FIG. 6B) of an example of a semiconductor package comprising a clip.

### DETAILED DESCRIPTION

In the following detailed description, reference is made to the accompanying drawings, which form a part hereof, and in which is shown by way of illustration specific embodiments in which the disclosure may be practiced. In this regard, directional terminology, such as “top”, “bottom”, “front”, “back”, “leading”, “trailing”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or multiple” unless specified otherwise or clear from context to be directed to a singular form. Also, at least one of A and B or the like generally means A or B or both A and B.

In addition, while a particular feature or aspect of an embodiment of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it should be understood that embodiments of the disclosure may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

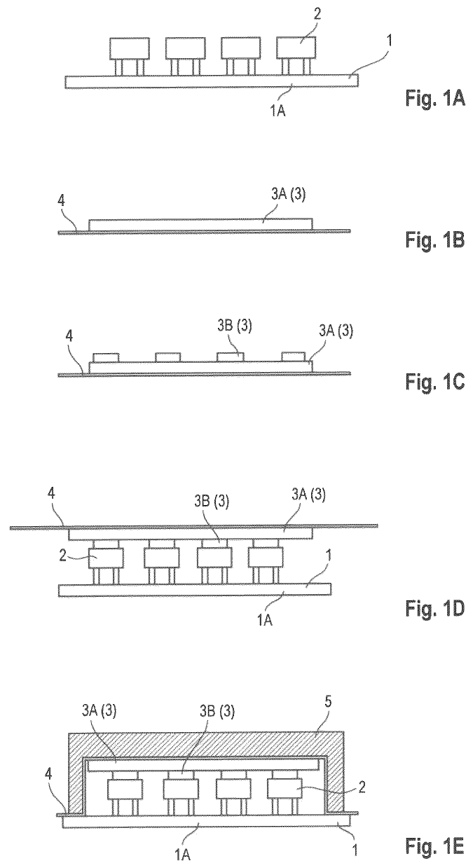

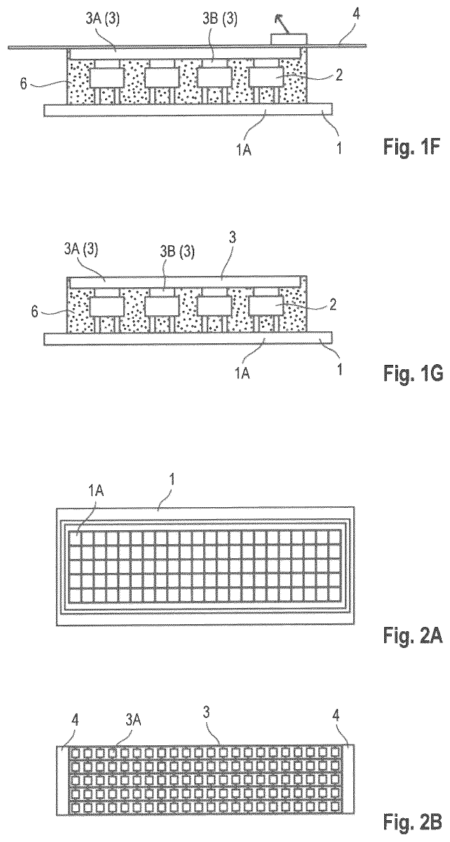

FIGS. 1A to 1G illustrate cross-sectional side views of an example of a method for fabricating semiconductor packages.

FIG. 1A shows a substrate layer 1 comprising electrical contact regions 1A and a plurality of semiconductor dies 2, each one of the semiconductor dies 2 electrically connected with one of the contact regions 1A. The substrate layer 1 can be, for example, a laminate strip or a printed circuit board. The semiconductor dies 2 can be, for example, GaN IGBT (insulated gate bipolar transistor) dies comprising a source contact and a gate contact on a lower thereof and a drain contact on an upper thereof.

FIG. 1B shows heat dissipation member 3 comprising one or more contact areas 3A and a tape 4 attached to a backside of the heat dissipation member 3 so that opposing ends of the tape 4 extend beyond opposing side edges of the heat dissipation member 3. The heat dissipation member 3 must first and be capable of heat dissipation and can be composed of electrically conductive (e.g. Cu), non-electrically conductive like a ceramic or a combination thereof like a direct copper bond (DCB). For embodiments where the heat dissipation member 3 may be non-electrically conductive, there is no need for predefined areas 3 which make contact with the die unlike embodiments where the heat dissipation member 3 is electrically conductive or a combination. More specifically, the heat dissipation member may comprise one or more of a leadframe, a direct copper bond (DCB), an active metal brazed (AMB), a passivated aluminum plate, an insulated metal substrate, a conductive clip or a ceramic material.

FIG. 1C shows the application of connection layers 3B on the contact areas 3A. The connection layers 3B can be, for example, hybrid Ag sintered layers 3B. This refers to a combination of sintering technology with conventional die attach epoxy materials, where the starting material of the sintering process is an epoxy resin layer filled with silver particles.

FIG. 1D shows the connecting of a frontside of the heat dissipation member 3 with the semiconductor die 2 by coupling the contact areas 3A via the connection layers 3B with the backside electrical contact of the semiconductor die 2. The use of the tape 4 makes the process resistant to stack-up tolerances of the stacked-up semiconductor dies 2, the connection layers 3B, and the heat dissipation member 3.

FIG. 1E shows placing a mold tool 5 above the heat dissipation member 3 and the substrate 1 with the opposing ends of the tape 4 extending out of the mold tool 5. It can be seen that after applying the mold tool 5 a first part of the tape 4 is disposed between the mold tool 5 and the heat dissipation member 3 and a second part of the tape 4 is disposed between the mold tool 5 and the substrate layer 1 so that a space between the mold tool 5 and the substrate layer 1 forms a mold cavity.

FIG. 1F shows an intermediate product after filling an encapsulant 6 into the mold cavity, curing the encapsulant 6, removing the mold tool 5 and removing the tape 4. Some mold flashes can remain on the tape 4, but do not affect the detaping. As indicated by the arrow, the mold flashes can well be removed by removing the tape 4.

FIG. 1G shows the finished semiconductor package. 2. After pulling out the tape 4, the whole assembly can be singulated into a plurality of essentially identical semiconductor packages like the one shown in FIG. 1G.

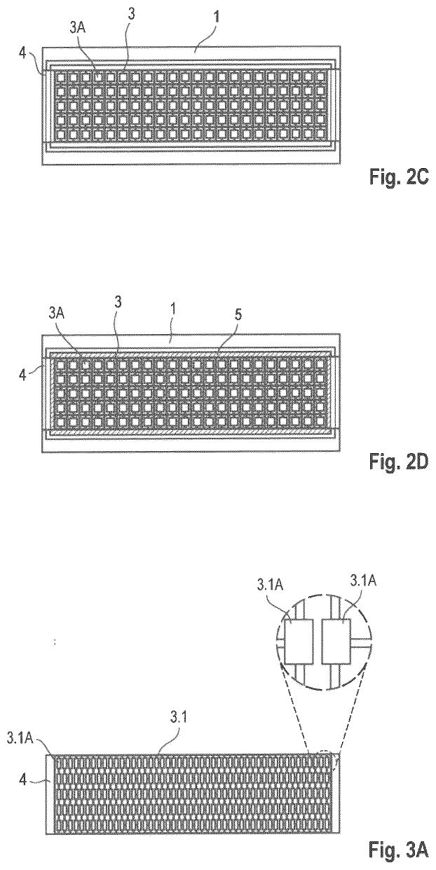

FIGS. 2A to 2D illustrate top views on a matrix-like arrangement of a plurality of contact areas of an example of a method for fabricating semiconductor packages.

FIG. 2A shows a substrate layer 1 comprising a plurality of electrical contact regions 1A. As was already mentioned in connection with FIGS. 1A-1G, the substrate layer 1 can be, for example, a laminate strip or a printed circuit board.

FIG. 2A further shows that the substrate layer 1 is provided with a regular arrangement of the plurality of electrical contact regions 1A, in particular a matrix-like arrangement. On each one of these electrical contact regions 1A a semiconductor die can be connected in the same way as was shown in FIG. 1A.

In a similar way, FIG. 2B shows a heat dissipation member 3 with a regular matrix-like arrangement of a plurality of contact areas 3A, wherein the matrix-like arrangement of the contact areas 3A is congruent with the matrix-like arrangement of the plurality of electrical contact regions 1A. A tape 4 is applied onto the contact areas 3A wherein opposing ends of the tape 4 extend over the opposing ends of the heat dissipation member 3.

FIG. 2C shows the assembly after attaching the matrix-like arrangement of the contact areas 3A onto the matrix-like arrangement of the electrical contact regions 1A after applying suitable connection layers to the contact areas 3A like, for example, the hybrid Ag sintered layers 3B which were shown in FIG. 1C.

FIG. 2D shows the assembly after molding where the bold outline indicates the mold tool 5. Thereafter the encapsulant is filled into the mold cavity and after curing the encapsulant the mold tool 5 is removed and the tape 4 pulled off.

The semiconductor dies (not shown in FIG. 2) can be, for example, GaN IGBT (insulated gate bipolar transistor) dies comprising a source contact and a gate contact on a lower surface thereof and a drain contact on an upper surface thereof.

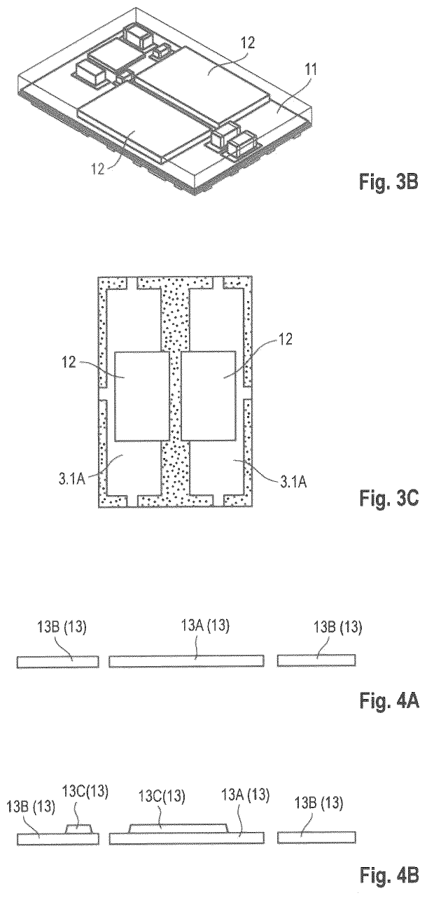

FIGS. 3A to 3C illustrate a top view on a matrix-like arrangement of a plurality of pairs of contact areas (FIG. 3A), a perspective view on a pair of two semiconductor dies disposed on a surface layer (FIG. 3B), and a top view on a finished package (FIG. 3C).

FIG. 3A shows a heat dissipation member 3.1 with a regular matrix-like arrangement of a plurality of contact areas 3.1A, wherein in contrast to the embodiment of FIG. 2, it is provided that in each case two electrical contact areas 3.1A are to be combined and are to be contacted with two semiconductor dies, both of which are equally to become part of a common circuit in a finished package. Two such electrical contact areas 3.1A belonging together in this way are shown in the dashed circle. A tape 4 is applied onto the contact areas 3A wherein opposing ends of the tape 4 extend over the opposing ends of the heat dissipation member 3.1. With regard to the materials of the heat dissipation member 3.1, the same applies as for the heat dissipation member 3 of FIG. 1.

FIG. 3B shows two semiconductor dies 12 attached to a substrate layer 11, wherein the two semiconductor dies 12 are to be connected with two electrical contact areas 3.1A. In a finished semiconductor package, the two semiconductor dies can form, for example, a high-side switch and a low-side switch of a half-bridge circuit. For this purpose, further components such as resistors or capacitors can be arranged on the surface layer 11. The two semiconductor dies 12 can be, for example, GaN IGBT (insulated gate bipolar transistor) dies comprising a source contact and a gate contact on a lower surface thereof and a drain contact on an upper surface thereof.

FIG. 3C shows a semiconductor package after singulation of the panel into a plurality of semiconductor packages. The tie bars previously connecting the two electrical contact areas 3.1A are removed after singulation, so that now the two electrical contact areas 3.1A are isolated from each other. As can be seen, a different distance can be provided between the electrical contact areas 3.1A than between the two semiconductor dies 12, a measure which can be designed for application purpose, e.g. providing a sufficient creepage distance.

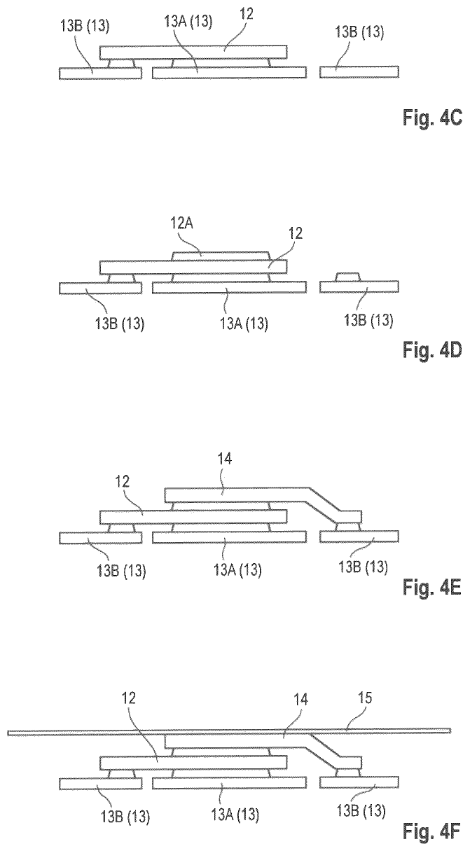

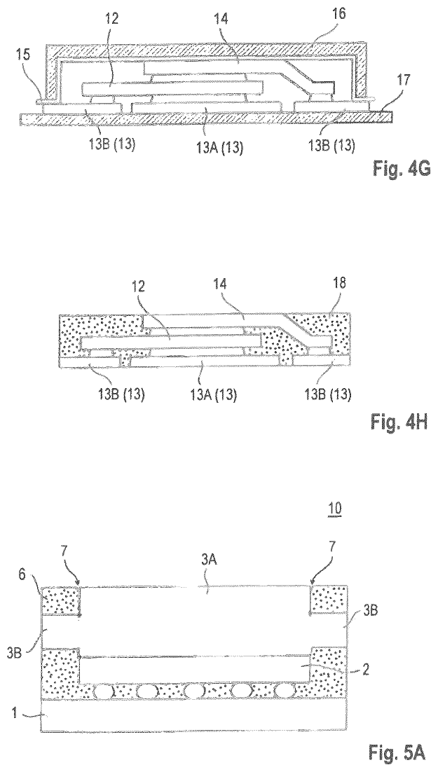

FIGS. 4A to 4H illustrate cross-sectional side views of an example of a method for fabricating a semiconductor package comprising a clip.

FIG. 4A shows a heat dissipation member 13 comprising one or more contact areas 13A and one or more contact elements 13B. With regard to the materials of the heat dissipation member 13, the same applies as for the heat dissipation member 3 of FIG. 1.

FIG. 4B shows the assembly after of connection layers 13C onto the contact areas 13A and the contact elements 13B. The connection layers 13C can be, for example, solder layers or sintered layers like those hybrid sintered layers as were described before. The application can be performed, e.g., by stencil printing.

FIG. 4C shows the assembly after application of a semiconductor die 12 onto the contact area 13A and one of the contact elements 13B. The semiconductor die 12 can be, for example, a GaN IGBT (insulated gate bipolar transistor) die comprising a source contact and a gate contact on a lower surface thereof and a drain contact on an upper surface thereof. The source contact may be connected with the contact area 13A and the gate contact may be connected with the left-sided contact element 13B.

FIG. 4D shows the assembly after application of a connection layer 12A onto an upper surface of the semiconductor die 12. The connection layer 12A can be, e.g., a solder layer.

FIG. 4E shows the assembly after applying a clip 14 and connecting the clip 14 between the semiconductor die 12 and the right-sided one of the contact elements 13B.

FIG. 4F shows the assembly after aattaching a tape 15 to a backside of the clip 14 so that opposing ends of the tape 15 extend beyond opposing side edges of the heat dissipation member 13.

FIG. 4G shows the assembly after placing an upper mold tool 16 above the clip 14 and one of the contact elements 13B and a lower mold tool 17 to a backside of the heat dissipation member 13 so that a first part of the tape 15 is disposed between the upper mold tool 16 and the clip 14 and a second part of the tape 15 is disposed between the upper mold tool 16 and the contact element 13B so that a space between the upper mold tool 16 and the lower mold tool 17 forms a mold cavity.

FIG. 4H shows the assembly after filling the mold cavity with an encapsulant 18, removing the upper mold tool 16 and the lower mold tool 17 after curing of the encapsulant 18, and removing the tape 15.

Instead of a clip 14 another type of electrical connector can be used.

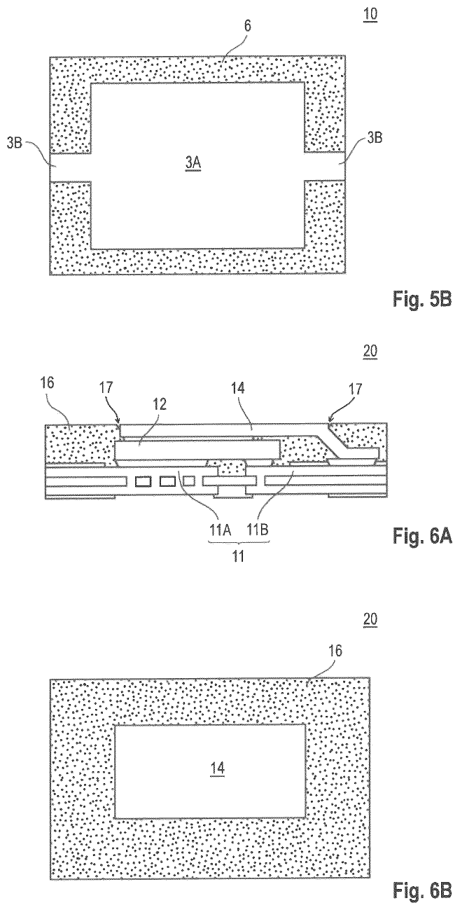

FIGS. 5A and 5B illustrate a cross-sectional side view (FIG. 5A) and a top view (FIG. 5B) of an example of a semiconductor package.

More specifically, FIG. 5A shows a semiconductor package 10 comprising a substrate layer 1, a heat dissipation member 3A, two tie bars 3B connected to opposing side face of the heat dissipation member 3A, a semiconductor die 2 disposed on the heat dissipation member 3A so that it is connected to the substrate layer 1 in a flip-chip configuration, an encapsulant 6 covering an upper face of the substrate layer 1 and partly embedding the semiconductor die 2, the heat dissipation member 3A and the two tie bars 3B, wherein a main face of the heat dissipation member 3A remote from the semiconductor die 2 and side faces of the two tie bars 3B are exposed to the outside.

The substrate layer 1 can be, for example, a laminate strip or a printed circuit board, and can comprise contact areas.

The semiconductor die 2 can be, for example, a GaN IGBT (insulated gate bipolar transistor) die comprising a source contact and a gate contact on a lower surface thereof and a drain contact on an upper surface thereof. The source contact may be connected with a first contact area of the substrate layer 1 and the gate contact may be connected with a second contact area of the substrate layer 1. The connections can be realized by solder balls as shown.

The semiconductor package 10 further comprises tape adhesive marks in the form of notches 7 in the encapsulant 6 at side edges of the heat dissipation member 3A. These notches 7 result from the fact that the tape used in the fabrication comprises an adhesive layer and when the copper surface is stuck to the adhesive layer, some adhesive will creep to the copper side wall. After removing the tape and the adhesive, the notches 7 remain in the places of the penetrated adhesive.

FIGS. 6A and 6B illustrate a cross-sectional side view (FIG. 6A) and a top view (FIG. 6B) of an example of a semiconductor package comprising a clip.

More specifically, FIG. 6A shows a semiconductor package 20 comprising a substrate layer 11 comprising a die pad 11A and a contact element 11B, a semiconductor die 12 connected to the die pad 11A in a flip-chip configuration, a clip 14 connected between an upper face of the semiconductor die 12 and the contact element 11B, an encapsulant 16 covering an upper face of the substrate layer 11 and partly embedding the semiconductor die 12, wherein a main face of the clip 14 remote from the semiconductor die 12 is exposed to the outside.

The substrate layer 11 can be, for example, a laminate strip or a printed circuit board, and can comprise contact areas 11A and 11B.

The semiconductor die 12 can be, for example, a GaN IGBT (insulated gate bipolar transistor) die comprising a source contact and a gate contact on a lower surface thereof and a drain contact on an upper surface thereof. The source contact may be connected with a first contact area 11A of the substrate layer 11 and the gate contact may be connected with a second contact area 11B of the substrate layer 11.

The semiconductor package 20 further comprises tape adhesive marks in the form of notches 17 in the encapsulant 16 at side edges of the electrical connector 14. As before with the notches 7 shown in FIG. 5A, also these notches 17 result from the fact that the tape used in the fabrication process comprises an adhesive layer and when the copper surface is stuck to the adhesive layer, some adhesive will creep to the copper side wall. After removing the tape and the adhesive, the notches 17 remain in the places of the penetrated adhesive.

Instead of a clip 14 another type of electrical connector can be used.

In the following specific examples of the present disclosure are described.
Example 1 is a method for fabricating one or more semiconductor packages, the method comprising providing a substrate layer comprising one or more electrical contact regions, connecting a semiconductor die with one of the electrical contact regions, providing a heat dissipation member comprising one or more contact areas, attaching a tape to a backside of the heat dissipation member so that opposing ends of the tape extend beyond opposing side edges of the heat dissipation member, connecting a frontside of the heat dissipation member with the semiconductor die by coupling at least one contact area with the semiconductor die, forming a mold cavity by placing a mold tool above the heat dissipation member and the substrate layer with the opposing ends of the tape extending out of the mold tool so that the tape is removable from outside the mold tool, filling an encapsulant into the mold cavity, and removing the tape.
Example 2 is the method according to Example 1, further comprising after pulling out the tape, singulating the assembly into the two or more semiconductor packages.
Example 3 is the method according to Example 2 for fabricating a plurality of semiconductor packages, further comprising providing the substrate layer with a regular arrangement of a plurality of electrical contact regions.
Example 4 is the method according to Example 3 for fabricating a plurality of semiconductor packages, further comprising providing the heat dissipation member with a regular arrangement of a plurality of contact areas.
Example 5 is the method according to Example 3 or 4, wherein the regular arrangement of the plurality of contact areas comprises a matrix-like arrangement.
Example 6 is the method according to Example 4 or 5, wherein the plurality of contact areas comprises a plurality of pairs of contact areas.
Example 7 is the method according to any one of the preceding Examples, wherein the substrate layer is one or more of a laminate layer, a printed circuit board (PCB), a leadframe, a direct copper bond (DCB), an active metal brazed (AMB), or an insulated metal substrate (IMS).
Example 8 is the method according to any one of the preceding Examples, wherein the heat dissipation member comprises one or more of a leadframe, a direct copper bond (DCB), an active metal brazed (AMB), a passivated aluminum plate, an insulated metal substrate, a conductive clip or a ceramic material.
Example 9 is the method according to any one of the preceding Examples, further comprising providing the tape so that after placing the mold tool above the heat dissipation member and the substrate layer, the tape extends to the outside of the mold tool by a length in a range from 2 mm to 4 mm.
Example 10 is the method according to any one of the preceding Examples, wherein the semiconductor die comprises ones or more of a semiconductor transistor die, a power transistor die, a GaN transistor die, or a SiC transistor die.
Example 11 is a method comprising providing a heat dissipation member comprising one or more contact areas and one or more contact elements, applying one or more semiconductor dies onto the one or more contact areas, connecting an electrical connector between the semiconductor die and one of the contact elements, attaching a tape to a backside of the electrical connector so that opposing ends of the tape extend beyond opposing side edges of the heat dissipation member, placing an upper mold tool above the electrical connector and one of the contact elements and a lower mold tool to a backside of the heat dissipation member so that a first part of the tape is disposed between the upper mold tool and the electrical connector and a second part of the tape is disposed between the upper mold tool and the contact element so that a space between the upper mold tool and the lower mold tool forms a mold cavity, filling the mold cavity with an encapsulant, and removing the tape.
Example 12 is the method according to Example 11, further comprising placing two or more semiconductor dies onto two or more contact areas, connecting two or more electrical connectors between the two or more semiconductor dies and one of the contact elements, placing an upper mold tool above the electrical connector and the two outermost contact elements, and after pulling out the tape, singulating the assembly into the two or more semiconductor packages.
Example 13 is the method according to Example 11 or 12, wherein the electrical connectors each comprise a clip.
Example 14 is the method according to any one of Examples 11 to 13, wherein the semiconductor die comprises one or more of a semiconductor transistor die, a power transistor die, a GaN transistor die, or a SiC transistor die.
Example 15 is a semiconductor package comprising a substrate layer, a heat dissipation member, at least one tie bar connected to a side face of the heat dissipation member, a semiconductor die disposed on the heat dissipation member so that it is connected to the substrate layer in a flip-chip configuration, an encapsulant covering an upper face of the substrate layer and partly embedding the semiconductor die, the heat dissipation member and the tie bar, wherein a main face of the heat dissipation member remote from the semiconductor die and a side face of the tie bar are exposed to the outside.
Example 16 is the semiconductor package according to Example 15, further comprising two tie bars connected to opposing side faces of the heat dissipation member and comprising side faces exposed to the outside.
Example 17 is the semiconductor package according to Example 15 or 16, further comprising tape adhesive marks in the form of notches in the encapsulant at side edges of the heat dissipation member.
Example 18 is a semiconductor package comprising a substrate layer comprising a die pad and a contact element, a semiconductor die connected to the die pad in a flip-chip configuration, an electrical connector connected between an upper face of the semiconductor die and the contact element, an encapsulant covering an upper face of the substrate layer and partly embedding the semiconductor die, wherein a main face of the electrical connector remote from the semiconductor die is exposed to the outside.
Example 19 is a semiconductor package according to Example 18, wherein the electrical connector comprises a clip.
Example 20 is a semiconductor package according to Example 18 or 19, further comprising tape adhesive marks in the form of notches in the encapsulant at side edges of the electrical connector.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed is:

1. A method for fabricating one or more semiconductor packages, the method comprising:
providing a substrate layer comprising one or more electrical contact regions;
connecting a semiconductor die with one of the one or more electrical contact regions;
providing a heat dissipation member comprising one or more contact areas;
attaching a tape to a backside of the heat dissipation member so that opposing ends of the tape extend beyond opposing side edges of the heat dissipation member;
connecting a frontside of the heat dissipation member with the semiconductor die by coupling at least one contact area with the semiconductor die;
forming a mold cavity by placing a mold tool above the heat dissipation member and the substrate layer with the opposing ends of the tape extending out of the mold tool so that the tape is removable from outside the mold tool;
filling an encapsulant into the mold cavity; and
removing the tape.

2. The method of claim 1, further comprising:
after removing the tape, singulating the assembly into two or more semiconductor packages.

3. The method of claim 2, further comprising:
providing the substrate layer with a regular arrangement of a plurality of electrical contact regions.

4. The method of claim 3, further comprising:
providing the heat dissipation member with a regular arrangement of a plurality of contact areas.

5. The method of claim 4, wherein the regular arrangement of the plurality of contact areas comprises a matrix-like arrangement.

6. The method of claim 4, wherein the plurality of contact areas comprises a plurality of pairs of contact areas.

7. The method of claim 1, wherein the substrate layer is one or more of a laminate layer, a printed circuit board, a leadframe, a direct copper bond, an active metal brazed, or an insulated metal substrate.

8. The method of claim 1, wherein the heat dissipation member comprises one or more of a leadframe, a direct copper bond, an active metal brazed, a passivated aluminum plate, an insulated metal substrate, a conductive clip, or a ceramic material.

9. The method of claim 1, further comprising:
providing the tape so that after placing the mold tool above the heat dissipation member and the substrate layer, the tape extends to the outside of the mold tool by a length in a range from 2 mm to 4 mm.

10. The method of claim 1, wherein the semiconductor die comprises ones or more of a semiconductor transistor die, a power transistor die, a GaN transistor die, or a SiC transistor die.

11. A method for fabricating a plurality of semiconductor packages, the method comprising:
providing a heat dissipation member comprising one or more contact areas and one or more contact elements;
applying one or more semiconductor dies onto the one or more contact areas;
connecting an electrical connector between the one or more semiconductor dies and one of the one or more contact elements;
attaching a tape to a backside of the electrical connector so that opposing ends of the tape extend beyond opposing side edges of the heat dissipation member;
placing an upper mold tool above the electrical connector and one of the one or more contact elements and a lower mold tool to a backside of the heat dissipation member, so that a first part of the tape is disposed between the upper mold tool and the electrical connector and a second part of the tape is disposed between the upper mold tool and the contact element and a space between the upper mold tool and the lower mold tool forms a mold cavity;
filling the mold cavity with an encapsulant; and
removing the tape.

12. The method of claim 11, further comprising:
placing two or more semiconductor dies onto two or more contact areas;
connecting two or more electrical connectors between the two or more semiconductor dies and one of the one or more contact elements;
placing the upper mold tool above the electrical connector and two outermost ones of the contact elements; and
after removing the tape, singulating the assembly into two or more semiconductor packages.

13. The method of claim 11, wherein the electrical connector comprises a clip.

14. The method of claim 11, wherein the two or more semiconductor dies comprise one or more of a semiconductor transistor die, a power transistor die, a GaN transistor die, or a SiC transistor die.

15. A semiconductor package, comprising:
a substrate layer;
a heat dissipation member;
at least one tie bar connected to a side face of the heat dissipation member;
a semiconductor die disposed on the heat dissipation member and connected to the substrate layer in a flip-chip configuration; and
an encapsulant covering an upper face of the substrate layer and partly embedding the semiconductor die, the heat dissipation member, and the at least one tie bar,
wherein a main face of the heat dissipation member remote from the semiconductor die and a side face of the at least one tie bar are exposed to the outside.

16. The semiconductor package of claim 15, further comprising:
two tie bars connected to opposing side faces of the heat dissipation member and comprising side faces exposed to the outside.

17. The semiconductor package of claim 15, further comprising:
tape adhesive marks in the form of notches in the encapsulant at side edges of the heat dissipation member.

18. A semiconductor package, comprising:
a substrate layer comprising a die pad and a contact element;
a semiconductor die connected to the die pad in a flip-chip configuration;
an electrical connector connected between an upper face of the semiconductor die and the contact element; and
an encapsulant covering an upper face of the substrate layer and partly embedding the semiconductor die, wherein a main face of the electrical connector remote from the semiconductor die is exposed to the outside.

19. The semiconductor package of claim 18, wherein the electrical connector comprises a clip.

20. The semiconductor package of claim 18, further comprising:
tape adhesive marks in the form of notches in the encapsulant at side edges of the electrical connector.
